(19) United States
(12) Patent Application Publication
(10) Pub. No.: US 2026/0304776 A1
(43) Pub. Date: Oct. 1, 2026

(54) SEMICONDUCTOR MEMORY DEVICE

(71) Applicant: Kioxia Corporation, Tokyo (JP)

(72) Inventors: Noritaka ISHIHARA, Nagoya (JP); Sho MORITA, Kuwana (JP)

(73) Assignee: Kioxia Corporation, Tokyo (JP)

(21) Appl. No.: 19/330,053

(22) Filed: Sep. 16, 2025

(30) Foreign Application Priority Data
Mar. 28, 2025 (JP) 2025-056045

(51) Int. Cl. H10B 43/35; H10B 41/10; H10B 41/27; H10B 41/35; H10B 43/10; H10B 43/27

(52) U.S. Cl. CPC H10B 43/35; H10B 41/10; H10B 41/27; H10B 41/35; H10B 43/10; H10B 43/27

(57) ABSTRACT

A semiconductor memory device includes: conductive layers; a semiconductor layer having an outer peripheral surface facing conductive layers, and containing one or more additive elements selected from the group consisting of carbon, nitrogen, oxygen, fluorine, and boron; a first insulating layer having an outer peripheral surface surrounded by the semiconductor layer; an electric charge accumulating layer provided between conductive layers and the semiconductor layer; and a second insulating layer provided between the electric charge accumulating layer and the semiconductor layer. The semiconductor layer includes: a first region and a second region contain the additive element; and a third region provided between the first and the second region. The third region does not contain the additive element, or average concentration values of the additive element in the first and the second region are higher than an average concentration value of the additive element in the third region.

### CROSS-REFERENCE TO RELATED APPLICATIONS

This application is based upon and claims the benefit of Japanese Patent Application No. 2025-056045, filed on Mar. 28, 2025, the entire contents of which are incorporated herein by reference.

### BACKGROUND

### Field

Embodiments described herein relate generally to a semiconductor memory device.

### Description of the Related Art

There has been known a semiconductor memory device that includes a plurality of conductive layers arranged in a first direction, a semiconductor layer extending in the first direction and having an outer peripheral surface facing the plurality of conductive layers, and an electric charge accumulating layer provided between the conductive layers and the semiconductor layer.

### BRIEF DESCRIPTION OF THE DRAWINGS

FIG. 1 is a schematic circuit diagram illustrating a configuration of a semiconductor memory device according to a first embodiment;

FIG. 2 is a schematic plan view illustrating the configuration of the semiconductor memory device;

FIG. 3 is an enlarged view of a part indicated by A in FIG. 2;

FIG. 4 is a cross-sectional view of a structure illustrated in FIG. 3 taken along line B-B′ and viewed in an arrow direction;

FIG. 5 is an enlarged view of a part indicated by C in FIG. 4;

FIG. 6 is a schematic graph illustrating an additive element concentration distribution obtained when the concentration of an additive element is measured along a virtual straight line L1 illustrated in FIG. 5;

FIG. 7 is a cross-sectional view of the structure illustrated in FIG. 4 taken along line D-D′ and viewed in an arrow direction;

FIG. 8 is a schematic cross-sectional view illustrating a manufacturing method of the semiconductor memory device according to the first embodiment;

FIG. 9 is a schematic cross-sectional view illustrating the manufacturing method;

FIG. 10 is a schematic cross-sectional view illustrating the manufacturing method;

FIG. 11 is a schematic cross-sectional view illustrating the manufacturing method;

FIG. 12 is a schematic cross-sectional view illustrating the manufacturing method;

FIG. 13 is a schematic cross-sectional view illustrating the manufacturing method;

FIG. 14 is a schematic cross-sectional view illustrating the manufacturing method;

FIG. 15 is a schematic cross-sectional view illustrating the manufacturing method;

FIG. 16 is a schematic cross-sectional view illustrating the manufacturing method;

FIG. 17 is a schematic cross-sectional view illustrating the manufacturing method;

FIG. 18 is a schematic cross-sectional view illustrating the manufacturing method;

FIG. 19 is a schematic cross-sectional view illustrating the manufacturing method;

FIG. 20 is a schematic cross-sectional view illustrating the manufacturing method; and

FIG. 21 is a schematic cross-sectional view illustrating the manufacturing method.

### DETAILED DESCRIPTION

A semiconductor memory device according to one embodiment comprises: a plurality of conductive layers arranged in a first direction; a semiconductor layer extending in the first direction, having an outer peripheral surface facing the plurality of conductive layers, and containing one or more additive elements selected from the group consisting of carbon (C), nitrogen (N), oxygen (O), fluorine (F), and boron (B); a first insulating layer extending in the first direction and having an outer peripheral surface surrounded by the semiconductor layer; an electric charge accumulating layer provided between the plurality of conductive layers and the semiconductor layer; and a second insulating layer provided between the electric charge accumulating layer and the semiconductor layer. The semiconductor layer includes: a first region that is provided between the first insulating layer and the second insulating layer and contains the additive element; a second region that is provided between the first region and the second insulating layer and contains the additive element; and a third region provided between the first region and the second region. The third region does not contain the additive element, or average concentration values of the additive element in the first region and the second region are higher than an average concentration value of the additive element in the third region.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the first configuration is disposed in a current path between the second configuration and the third configuration.

As used herein, when referring to a circuit or the like “electrically conducting” two wirings or the like, it may mean, for example, that the circuit or the like includes a transistor or the like, the transistor or the like is provided on a current path between the two wirings, and the transistor or the like is turned ON.

Semiconductor memory devices according to embodiments is described below with reference to the drawings.

### First Embodiment

### Configuration

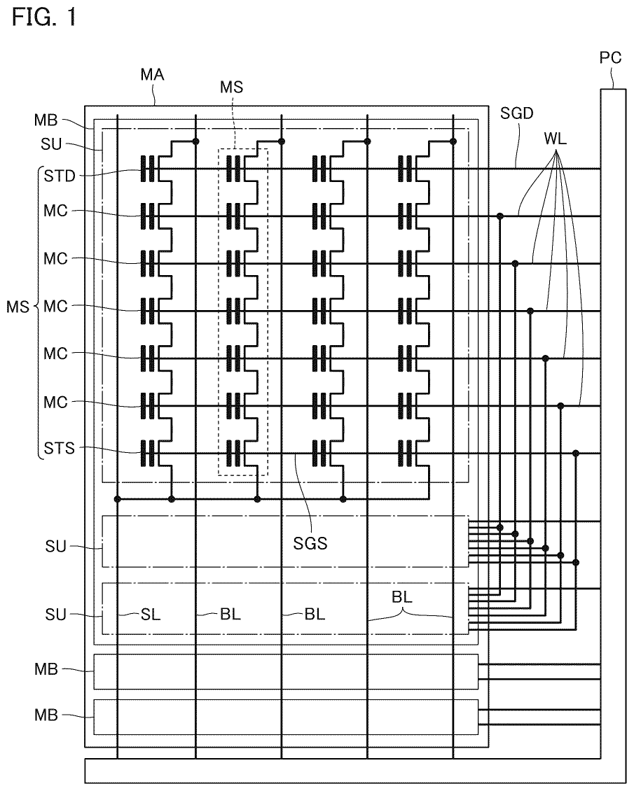

FIG. 1 is a schematic equivalent circuit diagram illustrating a configuration of a semiconductor memory device according to a first embodiment.

The semiconductor memory device according to the present embodiment includes a memory cell array MA and a peripheral circuit PC that controls the memory cell array MA.

The memory cell array MA includes a plurality of memory blocks MB. Each of these plurality of memory blocks MB includes a plurality of string units SU. Each of these plurality of string units SU includes a plurality of memory strings MS. Each of these plurality of memory strings MS has one end connected to the peripheral circuit PC via a bit line BL. Each of these plurality of memory strings MS has the other end connected to the peripheral circuit PC via a common source line SL.

The memory string MS includes a drain select transistor STD, a plurality of memory cells MC, and a source select transistor STS, which are connected in series between the bit line BL and the source line SL. Hereinafter, the drain select transistor STD and the source select transistor STS may be simply referred to as select transistors (STD, STS) or the like.

The memory cells MC are field-effect type transistors (memory transistors) each including a semiconductor layer that functions as a channel region, a gate insulating film including an electric charge accumulating film, and a gate electrode. The memory cell MC has a threshold voltage that changes in accordance with a charge amount in the electric charge accumulating film. The gate electrodes of a plurality of memory cells MC corresponding to one memory string MS are connected to respective word lines WL. These word lines WL are connected in common to all of the memory strings MS in one memory block MB.

The select transistors (STD, STS) are field-effect type transistors each including a semiconductor layer that functions as a channel region, a gate insulating film, and a gate electrode. Select gate lines (SGD, SGS) are connected to the gate electrodes of the select transistors (STD, STS), respectively. The drain select line SGD is provided corresponding to a string unit SU and is connected in common to all of the memory strings MS in one string unit SU. The source select line SGS is connected in common to all of the memory strings MS in a plurality of string units SU.

The peripheral circuit PC includes an operating voltage generation circuit that generates an operating voltage, an address decoder that decodes address data, a voltage transfer circuit that transfers the operating voltage to the memory cell array MA in accordance with an output signal from the address decoder, a sense amplifier that detects a current or a voltage of the bit lines BL, and a sequencer that controls them.

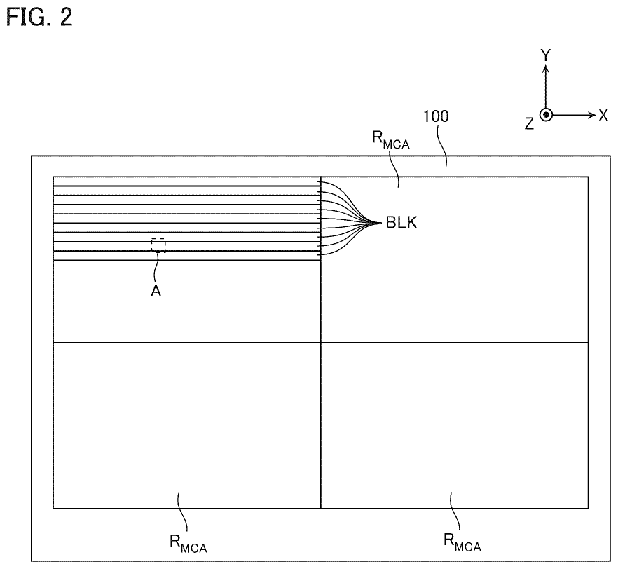

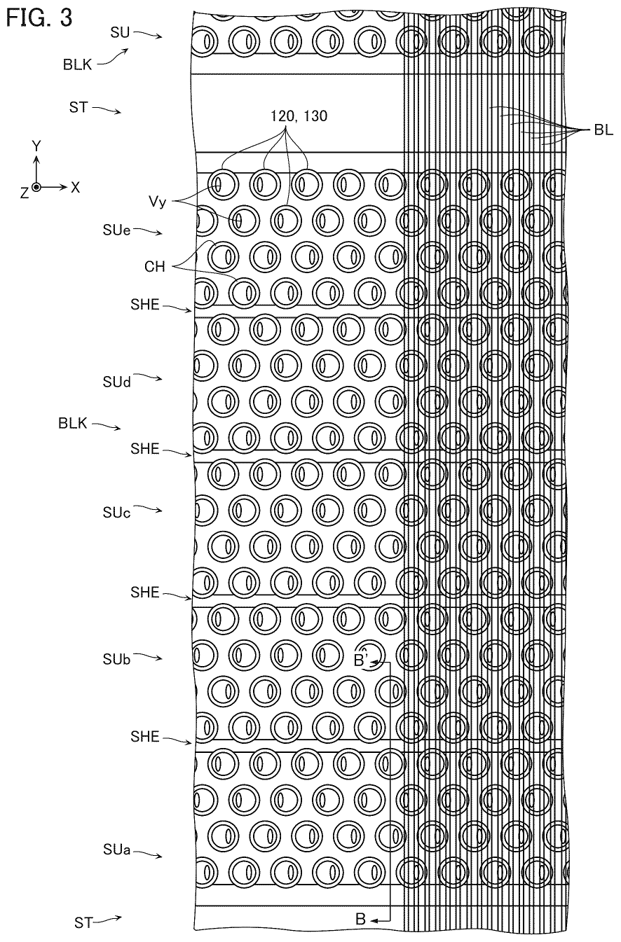

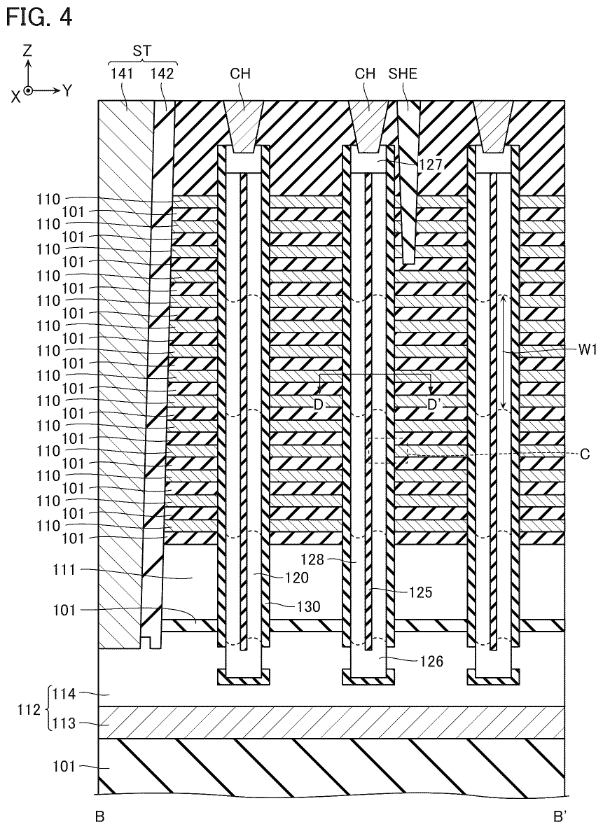

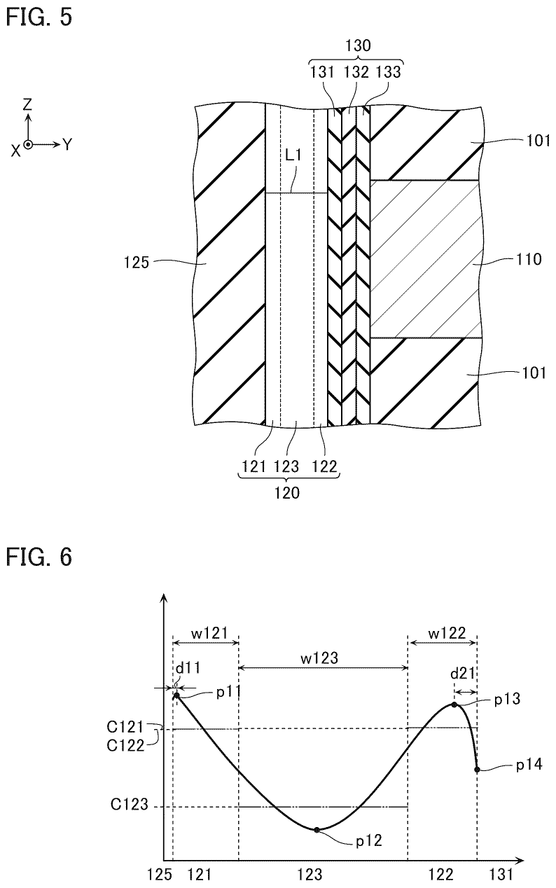

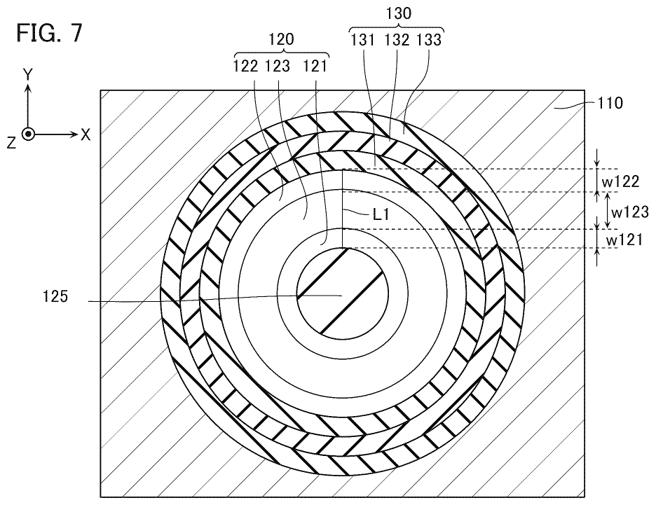

FIG. 2 is a schematic plan view of the semiconductor memory device according to the present embodiment. FIG. 3 is a schematic enlarged view of a part indicated by A in FIG. 2. FIG. 4 is a schematic cross-sectional view of a structure illustrated in FIG. 3 taken along line B-B′ and viewed in an arrow direction. FIG. 5 is a schematic enlarged view of a part indicated by C in FIG. 4. FIG. 6 is a graph illustrating a concentration distribution. FIG. 7 is a schematic cross-sectional view of the structure illustrated in FIG. 4 taken along line D-D′ and viewed in an arrow direction.

As illustrated in FIG. 2, the semiconductor memory device according to the present embodiment includes a semiconductor substrate 100. The semiconductor substrate 100 contains, for example, P-type silicon (Si) containing P-type impurities, such as boron (B).

The semiconductor substrate 100 has, for example, four memory cell array regions R_{MCA} arranged in an X-direction and a Y-direction. The memory cell array regions R_{MCA} each have a plurality of memory blocks BLK arranged in the Y-direction. For example, as illustrated in FIG. 3 and FIG. 4, an inter-block structure ST including a conductive layer 141 containing tungsten (W) or the like and an insulating layer 142 containing oxygen and silicon (for example, SiO₂) or the like is provided between two memory blocks BLK adjacent to each other in the Y-direction.

The memory block BLK includes a plurality of string units SU arranged in the Y-direction. In FIG. 3, five string units SU arranged in the Y-direction are denoted as string units SUa, SUb, SUc, SUd, and SUe from a negative side in the Y-direction. An inter-string unit insulating layer SHE containing oxide and silicon (for example, SiO₂) or the like is provided between two string units SU adjacent to each other in the Y-direction.

As illustrated in FIG. 3 and FIG. 4, the string unit SU includes a plurality of conductive layers 110 arranged in a Z-direction, a plurality of semiconductor layers 120 extending in the Z-direction, and a plurality of gate insulating layers 130 each provided between the conductive layers 110 and the semiconductor layer 120.

The conductive layers 110 function as the gate electrodes of the memory cells MC or the like and the word lines WL or the like. The conductive layers 110 are each an approximately plate-shaped conductive layer extending in the X-direction. For example, the conductive layer 110 may include a stacked film of nitrogen and titanium (for example, TiN) and tungsten (W) or may contain polycrystalline silicon (pSi) containing impurities such as phosphorus (P) or boron (B), or the like. Insulating layers 101 containing oxygen and silicon (for example, SiO₂) or the like are provided between the plurality of conductive layers 110 arranged in the Z-direction.

A conductive layer 111 is provided below the conductive layers 110. The conductive layer 111 functions as the gate electrode of the source select transistor STS and the source select line SGS. The conductive layer 111 may contain, for example, polycrystalline silicon (pSi) containing impurities such as phosphorus (P). An insulating layer 101 containing oxygen and silicon (for example, SiO₂) or the like is provided between the conductive layer 111 and the conductive layer 110.

A conductive layer 112 is provided below the conductive layer 111. The conductive layer 112 functions as the source line SL. The conductive layer 112 may include, for example, a conductive layer 113 containing a metal such as tungsten silicide (WSi) and a conductive layer 114 containing polycrystalline silicon (pSi) containing N-type impurities such as phosphorus (P), or the like. An insulating layer 101 containing oxygen and silicon (SiO₂) or the like is provided between the conductive layer 112 and the conductive layer 111.

The semiconductor layers 120 each function as the channel regions of a plurality of memory cells MC and the select transistors (STD, STS) included in one memory string MS (FIG. 1). The semiconductor layer 120 is a crystalline semiconductor layer containing, for example, polycrystalline or monocrystalline silicon (Si) or the like. The semiconductor layer 120 has, for example, an approximately closed-bottomed cylindrical shape and has an insulating layer 125 containing oxygen and silicon (for example, SiO₂) or the like in its center portion. The semiconductor layer 120 has an outer peripheral surface surrounded by the conductive layers 110.

The semiconductor layer 120 contains crystal grains, for example, having a size of 60 nm or more. The sizes of crystal grains here refers to the maximum width of crystal grains measured from multiple directions in a cross-section observed by an electron microscope or the like. For example, in the illustrated example, the semiconductor layer 120 contains crystal grains with sizes W1 of 60 nm or more in the Z-direction.

Impurity regions 126 and 127 containing N-type impurities such as phosphorus (P) are provided at lower and upper end portions of the semiconductor layer 120. Further, a region 128 that does not contain N-type impurities such as phosphorus (P) (or where the concentration of N-type impurities is lower than that of the impurity regions 126 and 127) is provided between the impurity regions 126 and 127. The impurity region 126 is connected to the conductive layer 114 and facing the conductive layer 111. The impurity region 127 is connected to the bit line BL (FIG. 3) via a contact CH and a contact Vy. The region 128 is facing the conductive layer 111 and all of the conductive layers 110 arranged in the Z-direction.

The gate insulating layers 130 each have an approximately closed-bottomed cylindrical shape covering the outer peripheral surface and a lower end of the semiconductor layer 120. However, the gate insulating layer 130 is not provided on a connection part between the semiconductor layer 120 and the conductive layer 114.

For example, as illustrated in FIG. 5, the gate insulating layer 130 includes a tunnel insulating layer 131, an electric charge accumulating layer 132, and a block insulating layer 133, which are stacked between the semiconductor layer 120 and the conductive layers 110. The tunnel insulating layer 131 and the block insulating layer 133 are, for example, insulating films including oxygen and silicon (for example, SiO₂) or like. The electric charge accumulating layer 132 is, for example, a film including nitrogen and silicon (for example, Si₃N₄) or the like that can store an electric charge. The tunnel insulating layer 131, the electric charge accumulating layer 132, and the block insulating layer 133 each have an approximately cylindrical shape and extend in the Z-direction along the outer peripheral surface of the semiconductor layer 120.

FIG. 5 illustrates the example in which the gate insulating layer 130 includes the electric charge accumulating layer 132 including nitrogen and silicon (Si₃N₄) or the like. However, the gate insulating layer 130 may include, for example, a floating gate of polycrystalline silicon (pSi) containing N-type or P-type impurities, or the like.

Referring now to FIG. 5 and FIG. 6, an additive element contained in the semiconductor layer 120 is described.

The semiconductor layer 120 contains an additive element. The additive element is one or more elements selected from the group consisting of carbon (C), nitrogen (N), oxygen (O), fluorine (F), and boron (B).

FIG. 6 is a schematic graph illustrating an additive element concentration distribution obtained when the concentration of the additive element is measured along a virtual straight line L1 set in a cross-section as illustrated in FIG. 5. The virtual straight line L1 is, for example, a straight line connecting a part of the insulating layer 125 and a part of the gate insulating layer 130. The straight line L1 extends in a direction that intersects the Z-direction, for example, in the X-direction or the Y-direction. The concentration distribution can be measured, for example, by an analysis method that combines transmission electron microscopy and energy-dispersive X-ray spectroscopy (TEM-EDX).

FIG. 6 illustrates a plurality of points p11 to p14 on the virtual straight line L1.

FIG. 6 also illustrates the semiconductor layer 120 divided into three regions, namely, a region 121, a region 123, and a region 122, from an insulating layer 125 side to a tunnel insulating layer 131 side. The region 121 is a region between the insulating layer 125 and the tunnel insulating layer 131. The region 122 is a region between the region 121 and the tunnel insulating layer 131. The region 123 is a region between the region 121 and the region 122.

The point p11 indicates a point at which the concentration of the additive element has the maximum value in the region 121. In the example illustrated in the drawing, the distance from the point p11 to an end portion on the insulating layer 125 side of the semiconductor layer 120 is denoted as a distance d11.

The point p12 indicates a point at which the concentration of the additive element has the minimum value in the region 123. In the example illustrated in the drawing, the concentration of the additive element decreases monotonously from the point p11 to the point p12.

The point p13 indicates a point at which the concentration of the additive element has the maximum value in the region 122. In the example illustrated in the drawing, the concentration of the additive element increases monotonously from the point p12 to the point p13. In the example illustrated in the drawing, the distance from the point p13 to an end portion on a gate insulating layer 130 side of the semiconductor layer 120 is denoted as a distance d21.

The point p14 indicates a point closest to the tunnel insulating layer 131 in the region 122. In the example illustrated in FIG. 6, the concentration of the additive element at the point p14 is lower than the concentration of the additive element at the point p13. Unlike the example illustrated in FIG. 6, the concentration of the additive element at the point p14 may be nearly equal to the concentration of the additive element at the point p13.

The distance d21 may be larger than the distance d11. In other words, the concentration peak of the additive element on the insulating layer 125 side is located very close to the insulating layer 125, whereas the concentration peak of the additive element on the tunnel insulating layer 131 side may be located slightly away from the tunnel insulating layer 131. The distance d11 may be zero.

In the example in FIG. 6, the average concentration values of the additive element in the regions 121, 123, and 122 are denoted as concentrations C121, C123, and C122, respectively. The concentrations C121 and C122 are higher than the concentration C123.

The concentrations C121 and C122 may be, for example, 1×10²⁰ atoms/cm³ or more and 2×10²¹ atoms/cm³ or less.

The region 123 may contain no additive element. As used herein, the term “the region 123 may contain no additive element” encompasses being equal to or below the lower limit of measurable concentration in the analysis method described above.

For example, in an XY cross-section in FIG. 7, the widths in a radial direction (a direction away from the center point of the insulating layer 125 and a direction toward the center point of the insulating layer 125) of the regions 121 and 122 that contain more additive element are smaller than the width in the radial direction of the region 123 that contains less or no additive element. For example, in the XY cross-section in FIG. 7, the width in the Y-direction of the region 121 is denoted as a width w121, the width in the Y-direction of the region 122 is denoted as a width w122, and the width in the Y-direction of the region 123 is denoted as a width w123. The width w123 is larger than the width w121 and the width w122.

### Manufacturing Method

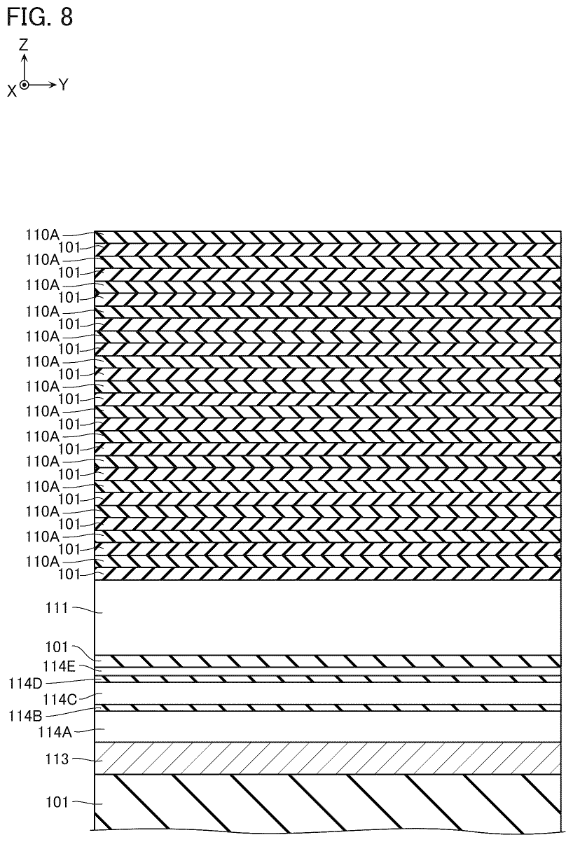

Referring now to FIG. 8 to FIG. 21, a manufacturing method of the semiconductor memory device according to the present embodiment is described. FIG. 8 to FIG. 21 are schematic cross-sectional views illustrating the manufacturing method.

In the manufacturing method, for example, as illustrated in FIG. 8, the conductive layer 113, a semiconductor layer 114A including silicon or the like, a sacrifice layer 114B including silicon oxide or the like, a sacrifice layer 114C including silicon or the like, a sacrifice layer 114D including silicon oxide or the like, a semiconductor layer 114E including silicon or the like, the insulating layer 101, and the conductive layer 111 are formed on the insulating layer 101. Further, a plurality of insulating layers 101 and a plurality of sacrifice layers 110A are alternately formed. This process is performed, for example, by a method such as chemical vapor deposition (CVD).

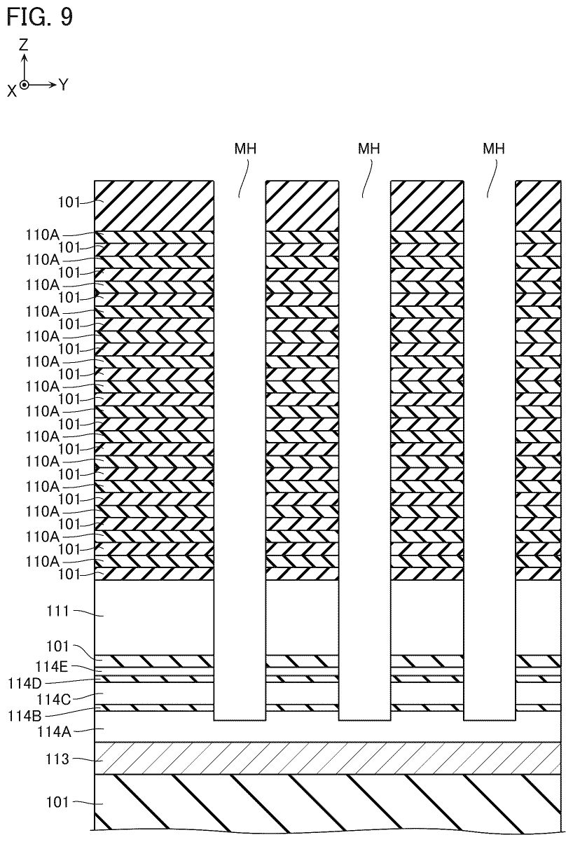

Next, for example, as illustrated in FIG. 9, openings MH are formed to pass through the plurality of insulating layers 101 and the plurality of sacrifice layers 110A, the conductive layer 111, the semiconductor layer 114E, the sacrifice layer 114D, the sacrifice layer 114C, and the sacrifice layer 114B, and extend in the Z-direction. This process is performed, for example, by a method such as reactive ion etching (RIE).

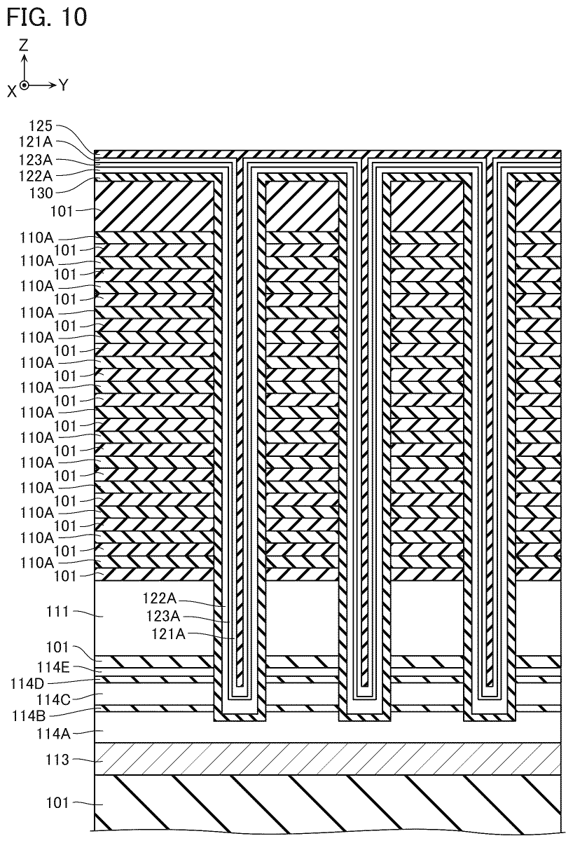

Next, for example, as illustrated in FIG. 10, the gate insulating layer 130, semiconductor layers 121A, 122A, and 123A including amorphous silicon (αSi) or the like, and the insulating layer 125 are formed inside the openings MH and on an upper surface of one of the plurality of insulating layers 101 that is located on the uppermost layer (hereinafter referred to as “insulating layer 101 located on the uppermost layer”). This process is performed, for example, by a method such as CVD. In the process of forming the semiconductor layers 121A and 122A, for example, a raw material gas containing the additive element described above may be used, and in the process of forming the semiconductor layer 123A, a raw material gas containing no additive element described above may be used. With such a process, the semiconductor layers 121A and 122A are formed as layers containing more additive element as described above.

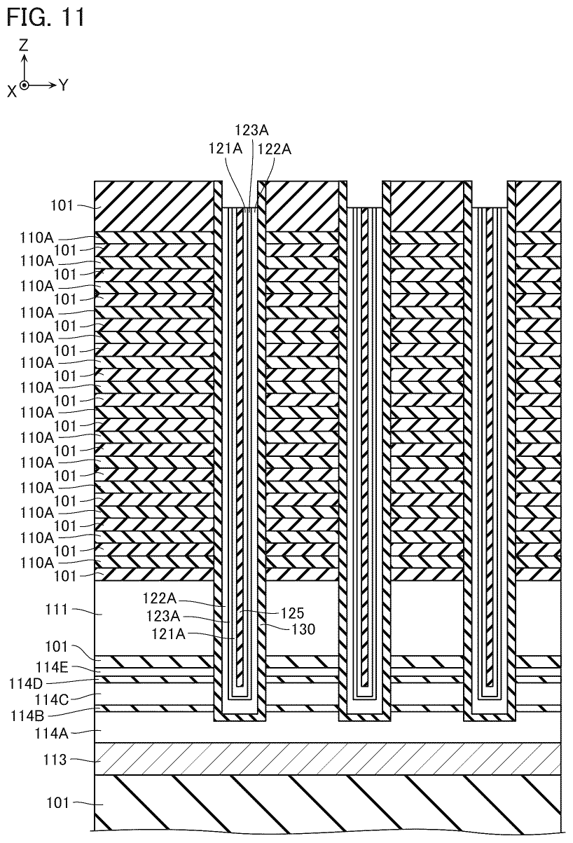

Next, for example, as illustrated in FIG. 11, in the gate insulating layer 130, the semiconductor layers 121A, 122A, and 123A, and the insulating layer 125, portions that are provided on an upper surface of the insulating layer 101 located on the uppermost layer and a part of portions that are surrounded by the insulating layer 101 located on the uppermost layer are removed. This process is performed, for example, by a method such as etch-back by RIE.

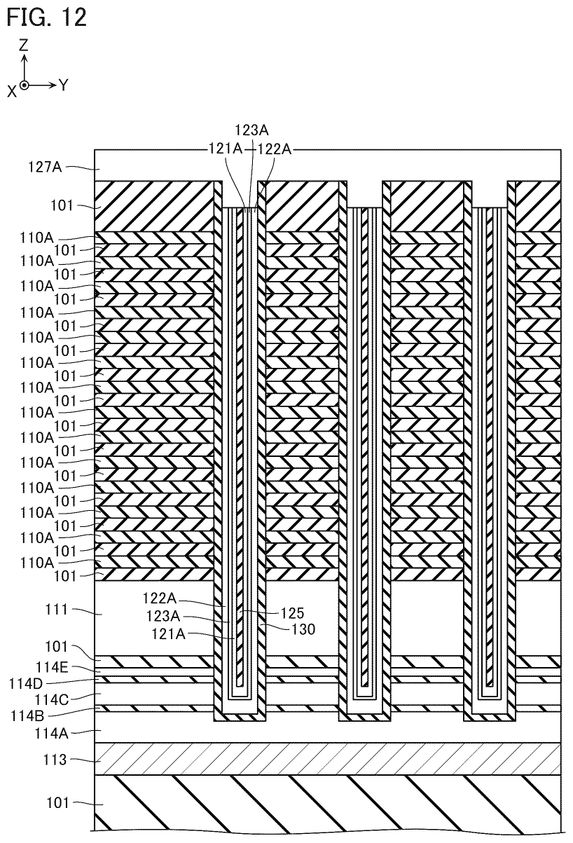

Next, for example, as illustrated in FIG. 12, a semiconductor layer 127A of amorphous silicon (αSi) or the like containing impurities such as phosphorus (P) is formed on upper ends of the semiconductor layers 121A, 122A, 123A and the insulating layer 125, and on the upper surface of the insulating layer 101 located on the uppermost layer. This process is performed, for example, by a method such as CVD.

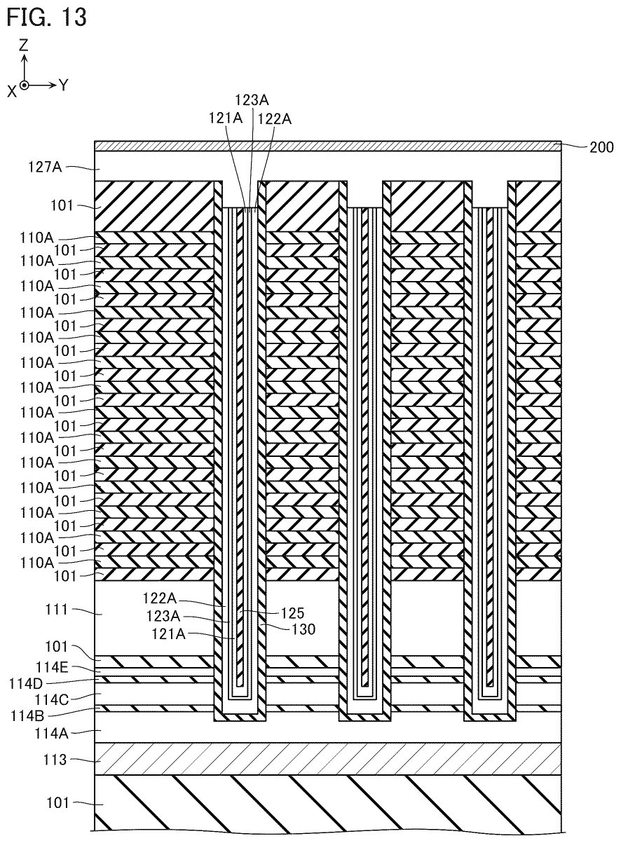

Next, for example, as illustrated in FIG. 13, a metal layer 200 is formed on an upper surface of the semiconductor layer 127A. The metal layer 200 contains, for example, one or more metallic elements among nickel (Ni), palladium (Pd), and aluminum (Al). The metal layer 200 is formed by depositing nickel (Ni), palladium (Pd), and aluminum (Al), or the like on the semiconductor layer 127A. The metal layer 200 thus may contain nickel silicide (NiSi), palladium silicide (PdSi), aluminum silicide (AlSi), or the like silicidized with the amorphous silicon (αSi) contained in the semiconductor layer 127A. This process is performed, for example, by a method such as sputtering or CVD.

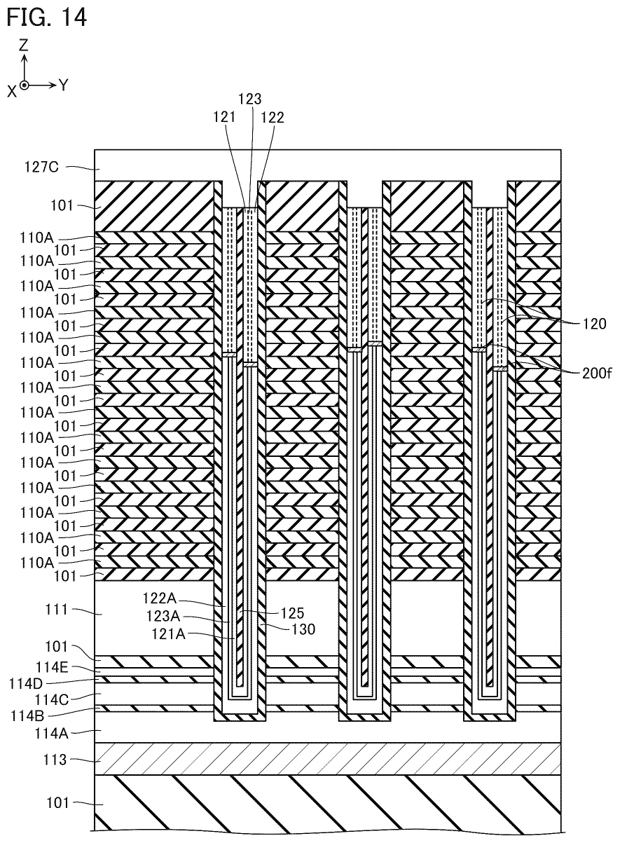

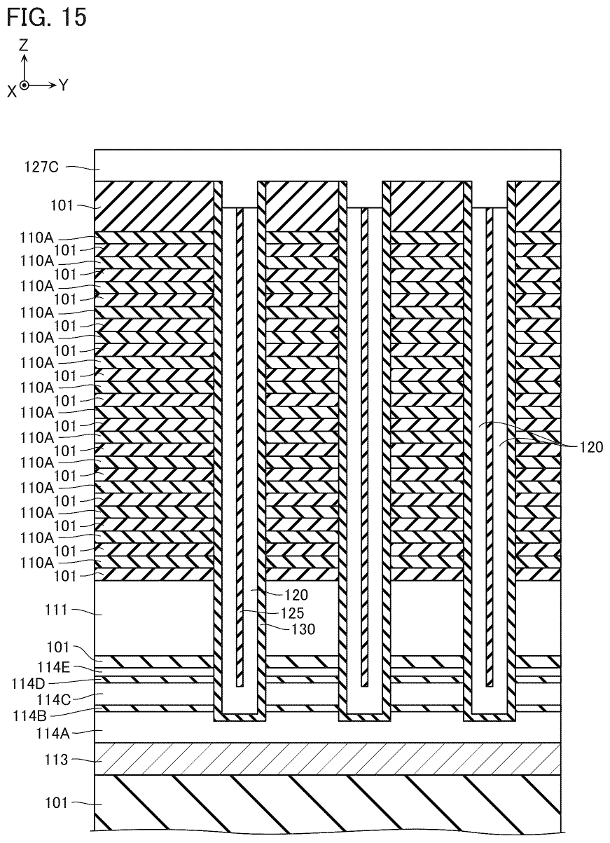

Next, for example, as illustrated in FIG. 14 and FIG. 15, a metal induced lateral crystallization (MILC) annealing process, which is a metal-assisted annealing process, is performed. FIG. 14 shows a state during the MILC annealing process, and FIG. 15 shows a state after completion of the MILC annealing process.

In the MILC annealing process, the metal layer 200 is arranged on one side (the upper side in FIG. 14) of the amorphous semiconductor layers 121A, 122A, 123A, and 127A to allow metal-assisted crystallization to proceed from a side closer to the metal layer 200 to a side far from the metal layer 200 (from the upper side to the lower side in FIG. 14).

The MILC annealing process is usually performed in a temperature range of 500° C. or higher and 600° C. or lower in which amorphous silicon (αSi) does not crystallize. As a result, the metal layer 200 acts as a catalyst to crystallize the amorphous semiconductor layer 127A and semiconductor layers 121A, 122A, and 123A. The crystallization proceeds through the movement of a plurality of portions 200f divided from the metal layer 200 from the side closer to the metal layer 200 to the side far from the metal layer 200.

The MILC annealing process modifies the crystal structure of the amorphous semiconductor layers 121A, 122A, 123A, and 127A to form the semiconductor layer 120 including the crystalline regions 123, 122, and 121 and a semiconductor layer 127C. If necessary, the metal contained in the metal layer 200 to serve as catalysts remaining in the semiconductor layers 121A, 122A, and 123A is removed by a gettering process.

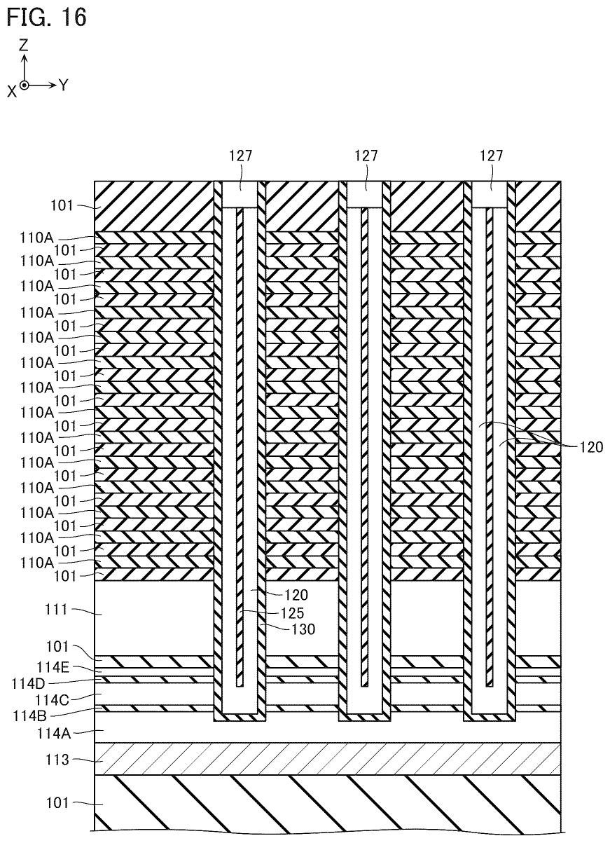

Next, for example, as illustrated in FIG. 16, a portion of the semiconductor layer 127C that is provided on the upper surface of the insulating layer 101 located on the uppermost layer is removed. Thus, the impurity regions 127 of the semiconductor layers 120 are formed. This process is performed, for example, by a method such as RIE.

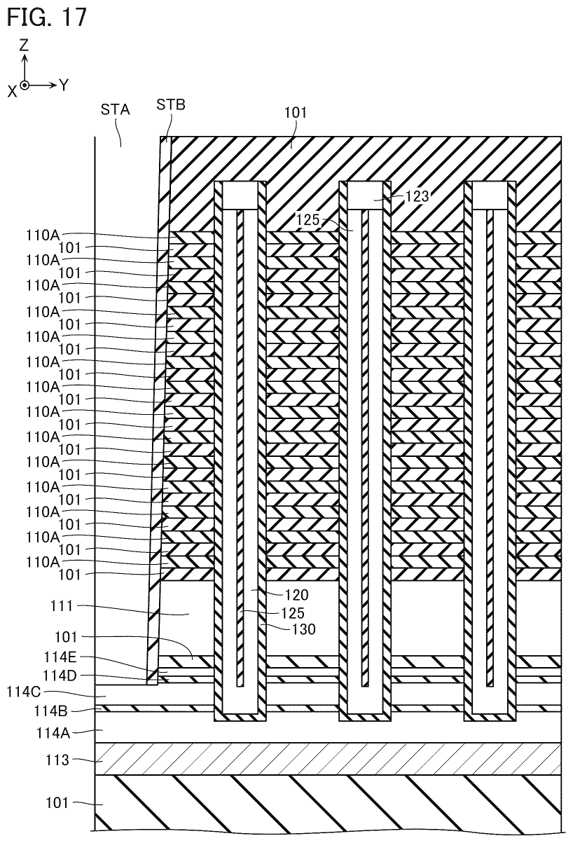

Next, for example, as illustrated in FIG. 17, the insulating layer 101 containing oxygen and silicon or the like is formed on upper surfaces of the impurity regions 127 and the insulating layer 101 located on the uppermost layer. Further, an opening STA is formed to pass through the plurality of insulating layers 101 and the plurality of sacrifice layers 110A, the conductive layer 111, the semiconductor layer 114E, and the sacrifice layer 114D, and extend in the X-direction and the Z-direction. This process is performed, for example, by a method such as RIE.

Further, a protective film STB containing nitrogen and silicon or the like is formed on a side surface in the Y-direction of the opening STA. This process is performed, for example, by a method such as CVD.

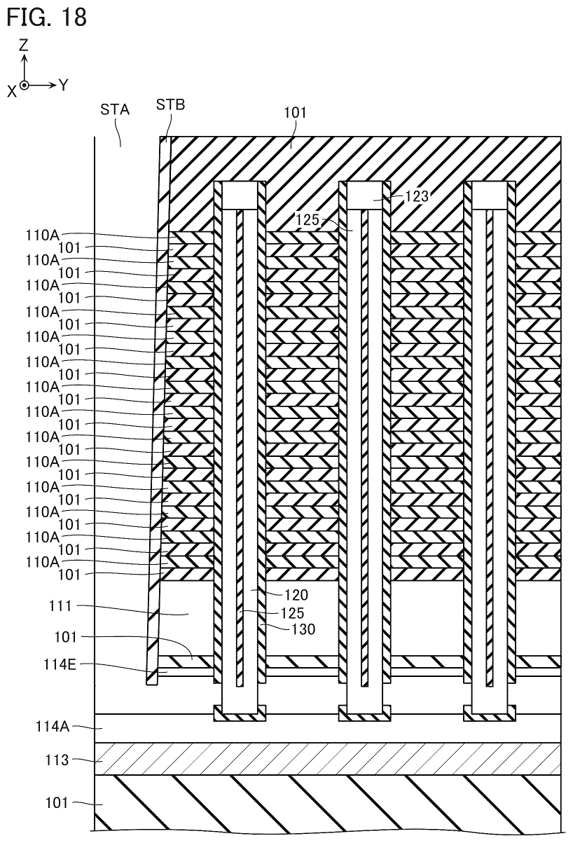

Next, for example, as illustrated in FIG. 18, the sacrifice layer 114C is removed. This process is performed, for example, by a method such as wet etching.

Further, the sacrifice layer 114B and the sacrifice layer 114D are removed. This process is performed, for example, by a method such as wet etching.

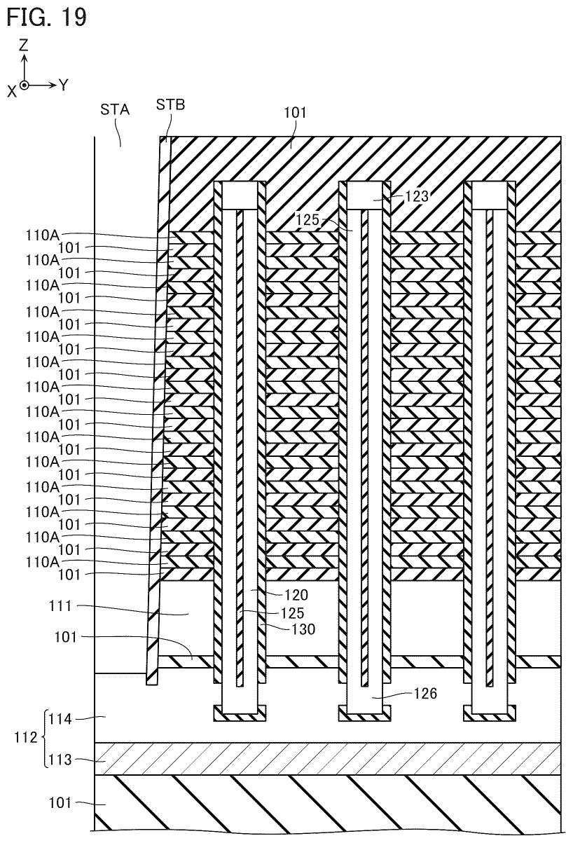

Next, for example, as illustrated in FIG. 19, the conductive layer 114 is formed. In this process, silicon (Si) containing impurities such as phosphorus (P) is formed on an upper surface of the semiconductor layer 114A and a lower surface of the semiconductor layer 114E, for example, by a method such as epitaxial growth.

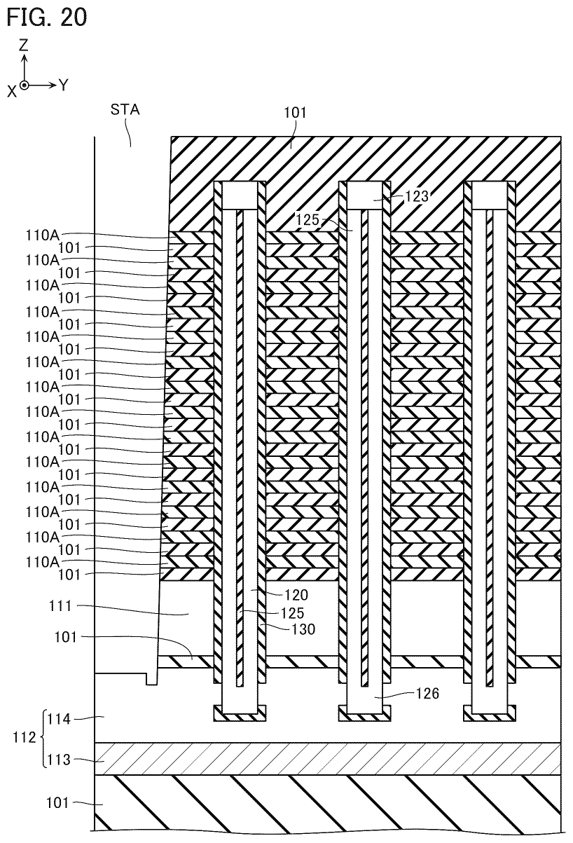

Next, for example, as illustrated in FIG. 20, the protective film STB is removed. This process is performed, for example, by a method such as wet etching.

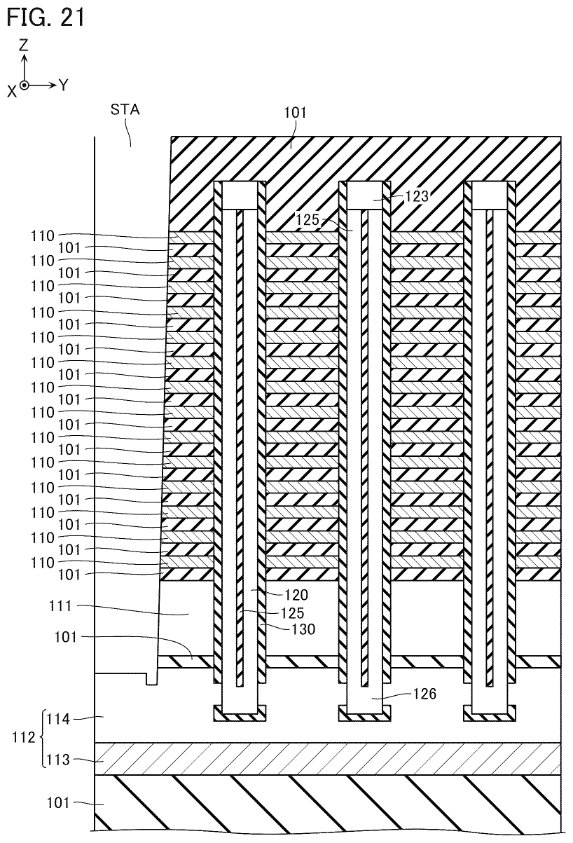

Next, for example, as illustrated in FIG. 21, the conductive layers 110 are formed. In this process, for example, the sacrifice layers 110A are removed by a method such as wet etching, and tungsten (W) or the like is formed in the portions from which the sacrifice layers 110A are removed, by a method such as CVD.

Subsequently, the inter-block structure ST (FIG. 4) is formed inside the opening STA by a method such as CVD, the inter-string unit insulating layer SHE (FIG. 4) is formed by a method such as RIE and CVD, and the contacts CH (FIG. 4) are formed by a method such as RIE and CVD. As a result, the structure described with reference to FIG. 4 and the like is formed.

### Effects

In the present embodiment, for example, as described with reference to FIG. 10, the gate insulating layer 130, the semiconductor layers 121A, 122A, and 123A of amorphous silicon (αSi) or the like, and the insulating layer 125 are formed inside the opening MH. The semiconductor layers 121A and 122A contain one or more additive elements selected from the group consisting of carbon (C), nitrogen (N), oxygen (O), fluorine (F), and boron (B).

In the present embodiment, for example, as described with reference to FIG. 14 and FIG. 15, the crystal structure of the semiconductor layers 121A, 122A, and 123A is modified by the metal-assisted annealing process.

As a result of elaborate studies by the inventors, it has been found that the sizes of crystal grains in the semiconductor layer 120 after crystallization can be increased by providing the semiconductor layers 121A and 122A containing high concentrations of the additive element on the insulating layer 125 side and on the gate insulating layer 130 side in the process illustrated in FIG. 14.

This is because the semiconductor layers 121A and 122A containing high concentrations of the additive element inhibit undesirable crystallization at the interfaces between the semiconductor layers 121A and 122A on the insulating layer 125 side and on the gate insulating layer 130 side, thereby enabling the MILC annealing process to be executed suitably.

For example, with such a method, as described with reference to FIG. 4, the sizes W1 of crystal grains in the semiconductor layer 120 can be 60 nm or more. As a result, the value of the electrical resistance value due to grain boundaries can be reduced when the memory cells MC are in ON state. In addition, OFF-leakage current due to grain boundaries can be reduced when the memory cells MC are in OFF state.

Further, as a result of elaborate studies by the inventors, it has been found that the above characteristics of the memory cells MC can be further improved by a concentration distribution in which the concentration peak of the additive element in the region 122 is located slightly away from the interface on the tunnel insulating layer 131 side of the semiconductor layer 120, for example, as described with reference to FIG. 6.

### Other Embodiments

The semiconductor memory device according to an embodiment has been described above. However, the description above is given only by way of example, and the configurations, methods, and the like described above can be adjusted as appropriate.

For example, in the MILC annealing process illustrated in FIG. 14, the metal layer 200 that functions as a catalyst is formed on an upper surface of the structure illustrated in FIG. 14. However, a position of the metal layer 200 that functions as a catalyst can be adjusted as appropriate.

For example, in the process described with reference to FIG. 10, a metal layer that functions as a catalyst may be provided after forming the semiconductor layer 121A, and this metal layer may be used to perform the metal-assisted annealing process to allow crystallization to proceed from the insulating layer 125 toward the gate insulating layer 130 side.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of conductive layers arranged in a first direction;
a semiconductor layer extending in the first direction, having an outer peripheral surface facing the plurality of conductive layers, and containing one or more additive elements selected from the group consisting of carbon (C), nitrogen (N), oxygen (O), fluorine (F), and boron (B);
a first insulating layer extending in the first direction and having an outer peripheral surface surrounded by the semiconductor layer;
an electric charge accumulating layer provided between the plurality of conductive layers and the semiconductor layer; and
a second insulating layer provided between the electric charge accumulating layer and the semiconductor layer, wherein
the semiconductor layer includes:
a first region that is provided between the first insulating layer and the second insulating layer and contains the additive element;
a second region that is provided between the first region and the second insulating layer and contains the additive element; and
a third region provided between the first region and the second region, and
the third region does not contain the additive element, or average concentration values of the additive element in the first region and the second region are higher than an average concentration value of the additive element in the third region.

2. The semiconductor memory device according to claim 1, wherein
in a cross-section extending in the first direction and a second direction intersecting with the first direction, and including the first insulating layer,
a width in the second direction of the third region is larger than widths in the second direction of the first region and the second region.

3. The semiconductor memory device according to claim 1, wherein
the average concentration values of the additive element in the first region and the second region are 1×10²⁰ atoms/cm³ or more and 2×10²¹ atoms/cm³ or less.

4. The semiconductor memory device according to claim 1, wherein
the semiconductor layer contains a crystal grain with a size of 60 nm or more.

5. The semiconductor memory device according to claim 1, wherein
in a cross-section extending in the first direction and a second direction intersecting with the first direction, and including the first insulating layer,
when the additive element concentration in the first region is measured along a virtual first straight line extending in the second direction, a point on the first straight line at which the additive element concentration has a maximum value is a first point,
when the additive element concentration in the second region is measured along the first straight line, a point on the first straight line at which the additive element concentration has a maximum value is a second point, and
a distance from the first point to an end portion on a first insulating layer side of the semiconductor layer is smaller than a distance from the second point to an end portion on a second insulating layer side of the semiconductor layer.

6. The semiconductor memory device according to claim 1, wherein
the semiconductor layer contains polycrystalline silicon (Si) or monocrystalline silicon (Si).

7. A semiconductor memory device comprising:
a plurality of conductive layers arranged in a first direction;
a semiconductor layer extending in the first direction, having an outer peripheral surface facing the plurality of conductive layers, and containing one or more additive elements selected from the group consisting of carbon (C), nitrogen (N), oxygen (O), fluorine (F), and boron (B);
a first insulating layer extending in the first direction and having an outer peripheral surface surrounded by the semiconductor layer;
an electric charge accumulating layer provided between the plurality of conductive layers and the semiconductor layer; and
a second insulating layer provided between the electric charge accumulating layer and the semiconductor layer, wherein
the semiconductor layer includes:
a first region that is provided between the first insulating layer and the second insulating layer and contains the additive element;
a second region that is provided between the first region and the second insulating layer and contains the additive element; and
a third region provided between the first region and the second region, and
in a cross-section extending in the first direction and a second direction intersecting with the first direction, and including the first insulating layer,
when a concentration of the additive element in the first region is measured along a virtual first straight line extending in the second direction, a point on the first straight line at which the additive element concentration has a maximum value is a first point,
when a concentration of the additive element in the second region is measured along the first straight line, a point on the first straight line at which the additive element concentration has a maximum value is a second point, and
a distance from the first point to an end portion on a first insulating layer side of the semiconductor layer is smaller than a distance from the second point to an end portion on a second insulating layer side of the semiconductor layer.

8. The semiconductor memory device according to claim 7, wherein
the additive element concentrations at the first point and the second point are 1×10²⁰ atoms/cm³ or more and 2×10²¹ atoms/cm³ or less.

9. The semiconductor memory device according to claim 7, wherein
the semiconductor layer contains a crystal grain with a size of 60 nm or more.

10. The semiconductor memory device according to claim 7, wherein
the semiconductor layer contains polycrystalline silicon (Si) or monocrystalline silicon (Si).

11. A manufacturing method of a semiconductor memory device, comprising the steps of:
forming a plurality of first layers and a plurality of second layers alternately arranged in a first direction;
forming an opening penetrating the plurality of first layers and the plurality of second layers and extending in the first direction;
forming an electric charge accumulating film and a first insulating film inside the opening;
forming an amorphous first semiconductor film inside the opening, the first semiconductor film being in contact with the first insulating film and containing one or more additive elements selected from the group consisting of carbon (C), nitrogen (N), oxygen (O), fluorine (F), and boron (B);
forming an amorphous second semiconductor film inside the opening, the second semiconductor film being in contact with the first semiconductor film, and not containing the additive element or having an average concentration value of the additive element lower than an average concentration value of the additive element in the first semiconductor film;
forming an amorphous third semiconductor film inside the opening, the third semiconductor film being in contact with the second semiconductor film and containing the additive element;
forming a first insulating layer inside the opening, the first insulating layer having an outer peripheral surface surrounded by the third semiconductor film;
forming a fourth semiconductor film in contact with end portions in the first direction of the first semiconductor film, the second semiconductor film, and the third semiconductor film;
forming a metal layer in contact with the fourth semiconductor film and silicidizing a part of the fourth semiconductor film to form silicide; and
performing an annealing process in the state where the silicide is formed to crystallize the first semiconductor film, the second semiconductor film, the third semiconductor film, and the fourth semiconductor film.

12. The manufacturing method of a semiconductor memory device according to claim 11, wherein
the first semiconductor film, the second semiconductor film, and the third semiconductor film crystallized through the annealing process contain a crystal grain with a size of 60 nm or more.

13. The manufacturing method of a semiconductor memory device according to claim 11, wherein
the first semiconductor film and the third semiconductor film are formed to have film thicknesses in a second direction intersecting with the first direction thinner than a film thickness in the second direction of the second semiconductor film.

14. The manufacturing method of a semiconductor memory device according to claim 11, wherein
average concentration values of the additive element in the first semiconductor film and the third semiconductor film are 1×10²⁰ atoms/cm³ or more and 2×10²¹ atoms/cm³ or less.

15. The manufacturing method of a semiconductor memory device according to claim 11, wherein
the first semiconductor film, the second semiconductor film, the third semiconductor film, and the fourth semiconductor film contain amorphous silicon (αSi).

16. The manufacturing method of a semiconductor memory device according to claim 11, wherein
the metal layer contains one or more metallic elements among nickel (Ni), palladium (Pd), and aluminum (Al).
